(19) United States
(12) Patent Application Publication
(10) Pub. No.: US 2015/0260751 A1
(43) Pub. Date: Sep. 17, 2015

(54) DETECTOR MODULE FOR MEMS SENSOR AND MEMS SENSOR HAVING THE SAME

(71) Applicant: SAMSUNG ELECTRO-MECHANICS CO., LTD., Gyeonggi-Do (KR)

(72) Inventors: Won HAN, Gyeonggi-Do (KR); Jong Woon KIM, Gyeonggi-Do (KR)

(73) Assignee: SAMSUNG ELECTRO-MECHANICS CO., LTD., Gyeonggi-Do (KR)

(21) Appl. No.: 14/323,388

(22) Filed: Jul. 3, 2014

(30) Foreign Application Priority Data
Mar. 14, 2014 (KR) 10-2014-0030544

(51) Int. Cl. G01P 15/12; B81B 3/00

(52) U.S. Cl. CPC G01P 15/123; B81B 3/0062

(57) ABSTRACT

Embodiments of the invention provide a detector module for a MEMS sensor. The detector module includes a mass body, a fixed part disposed to be spaced apart from the mass body, and a flexible part configured to connect the mass body to the fixed part. The flexible part includes a first flexible part, which is a beam configured to connect the mass body to the fixed part, and a second flexible part, which is a hinge configured to extend to the first flexible part, to connect the mass body to the fixed part, and to limit a displacement of the mass body.

### CROSS REFERENCE TO RELATED APPLICATION

This application claims the benefit of and priority under 35 U.S.C. §119 to Korean Patent Application No. KR 10-2014-0030544, entitled “DETECTOR MODULE FOR MEMS SENSOR AND MEMS SENSOR HAVING THE SAME,” filed on Mar. 14, 2014, which is hereby incorporated by reference in its entirety into this application.

### BACKGROUND

1. Field of the Invention

The present invention relates to a detector module for a micro-electro-mechanical system (MEMS) sensor and a MEMS sensor having the same.

2. Description of the Related Art

Recently, a sensor has been used in various fields, for example, the military, such as an artificial satellite, a missile, and an unmanned aircraft, as non-limiting examples, vehicles, such as an air bag, electronic stability control (ESC), and a black box for a vehicle, as non-limiting examples, and hand shaking prevention of a camcorder, motion sensing of a mobile phone or a game machine, and navigation, as non-limiting examples.

The sensor generally adopts a configuration in which a mass body is adhered to an elastic substrate, such as a membrane in order to measure acceleration, angular velocity, force, as non-limiting examples. Through the configuration, the sensor may calculate the acceleration by measuring inertial force applied to the mass body, calculate the angular velocity by measuring Coriolis force applied to the mass body, and calculate the force by measuring external force directly applied to the mass body.

Meanwhile, the sensor according to the conventional art includes beams extended in an X axis direction and a Y axis direction in order to drive the mass body or sense displacement of the mass body, as described, for example, in U.S. Patent Publication No. 2009/0282918. However, in the conventional sensor, the beam extending in the X-axis direction basically has the same rigidity as the beam extending in the Y-axis direction, such that crosstalk may occur at the time of measuring acceleration or interference of a resonance mode may occur at the time of measuring angular velocity. Due to the crosstalk or the interference of the resonance mode, the sensor according to the prior art detects a force in an unwanted direction and thus sensitivity may be reduced and a beam basically implements a parallel rigidity disposition and thus rigidity may be increased and sensitivity may be reduced.

### SUMMARY

Accordingly, embodiments of the invention have been made to provide a detector module for a MEMS sensor and a MEMS sensor having the same capable of removing crosstalk or interference of a resonance mode and reducing rigidity using a single flexible part to improve sensitivity.

According to an embodiment of the invention, there is provided a detector module for a MEMS sensor, including a mass body, a fixed part disposed to be spaced apart from the mass body, and a flexible part connecting the mass body to the fixed part. According to an embodiment, the flexible part includes a first flexible part, which is a beam connecting the mass body to the fixed part and a second flexible part, which is a hinge extending to the first flexible part, connecting the mass body to the fixed part, and limiting a displacement of the mass body.

According to an embodiment, the second flexible part is configured to extend in an orthogonal direction to a direction in which the first flexible part connects the mass body to the fixed part.

According to an embodiment, the first flexible part is a beam having a predetermined thickness in a Z-axis direction and having a surface formed by an X axis and a Y axis and is formed so that a width in an X-axis direction is larger than a thickness in a Z-axis direction.

According to an embodiment, the second flexible part is a hinge having a predetermined thickness in a Y-axis direction and having a surface formed by an X axis and a Y axis and is formed so that a width in a Z-axis direction is larger than a thickness in a Y-axis direction.

According to an embodiment, the second flexible part is positioned corresponding to a center of gravity of the mass body based on the X-axis direction.

According to an embodiment, one end surface of the second flexible part is vertically coupled with the first flexible part and the end surface thereof is formed in a “T”-letter shape.

According to an embodiment, the other end surface of the second flexible part is positioned on the same surface with a lower end surface of the mass body.

According to an embodiment, the first flexible part is applied with a bending stress and the second flexible part is applied with a torsion stress, by the displacement of the mass body.

According to an embodiment, one surface of the first flexible part or the second flexible part is selectively provided with a sensor, which senses the displacement of the mass body.

According to an embodiment, the sensor includes a plurality of piezoresistors and wirings connecting between the piezoresistors.

According to an embodiment, the plurality of piezoresistors include a first piezoresistor, a second piezoresistor, a third piezoresistor, and a fourth piezoresistor, and the piezoresistors, which are in the same stress state among the plurality of piezoresistors, are connected to each other by the wirings.

According to an embodiment, two or four of the first piezoresistor, the second piezoresistor, the third piezoresistor, and the fourth piezoresistor are selectively connected to each other by the wirings.

According to an embodiment, the second flexible parts are each connected to both sides of the mass body, the second flexible parts are each provided with the plurality of piezoresistors, and the plurality of piezoresistors are connected to each other by the wirings through the mass body.

According to another embodiment of the invention, there is provided a detector module for a MEMS sensor, including a mass body, a fixed part disposed to be spaced apart from the mass body, and a flexible part connecting the mass body to the fixed part. According to an embodiment, the flexible part includes a first flexible part, which is a beam connecting the mass body to the fixed part and a second flexible part, which is a hinge extending to the first flexible part, connecting the mass body to the fixed part, and limiting a displacement of the mass body, and further including a sensor detecting the displacement of the mass body. According to an embodiment, the sensor includes an electrode part formed on one surface of the mass body and an electrode part formed at the fixed part facing the electrode part of the mass body.

According to still another embodiment of the invention, there is provided a MEMS sensor including a mass body, a post fitted with the mass body, and a flexible beam connecting the mass body to the post. According to an embodiment, the flexible beam includes a first flexible part, which is a beam connecting the mass body to the post, a second flexible part, which is a hinge coupled with the first flexible part, connecting the mass body to the post, and limiting a displacement of the mass body, and a sensor selectively provided on one surface of the first flexible part or the second flexible part and sensing the displacement of the mass body.

According to an embodiment, the second flexible part is configured to extend in an orthogonal direction to a direction in which the first flexible part connects the mass body to the post.

According to an embodiment, the first flexible part is a beam which has a predetermined thickness in a z-axis direction and has a surface formed by an X axis and a Y axis, and the second flexible part is a hinge which has a predetermined thickness in a Y-axis direction and has a surface formed by the X axis and a Z axis.

According to an embodiment, one end surface of the second flexible part is vertically coupled with the first flexible part and an end surface of a flexible beam is formed in a “T”-letter shape.

According to an embodiment, the sensor includes a plurality of piezoresistors and wirings connecting between the piezoresistors.

According to an embodiment, the plurality of piezoresistors include a first piezoresistor, a second piezoresistor, a third piezoresistor, and a fourth piezoresistor, and the piezoresistors, which are in the same stress state among the plurality of piezoresistors, are connected to each other by the wirings.

According to an embodiment, two or four of the first piezoresistor, the second piezoresistor, the third piezoresistor, and the fourth piezoresistor are selectively connected to each other by the wirings.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a plan view of a detector module for a MEMS sensor according to a first embodiment of the invention.

FIG. 2 is a schematic cross-sectional view taken along the line A-A′ of the detector module for a MEMS sensor illustrated in FIG. 1 according to the first embodiment of the invention.

FIG. 3 is a plan view illustrating an example of a sensor which is formed in the detector module for a MEMS sensor according to the first embodiment of the invention.

FIG. 4A is a partial plan view illustrating a first example of a connection wiring of the sensor in the detector module for a MEMS sensor illustrated in FIG. 3 according to the first embodiment of the invention.

FIG. 4B is a partial plan view illustrating a second example of the connection wiring of the sensor in the detector module for a MEMS sensor illustrated in FIG. 3 according to the first embodiment of the invention.

FIG. 4C is a partial plan view illustrating a third example of the connection wiring of the sensor in the detector module for a MEMS sensor invention illustrated in FIG. 3 according to the first embodiment of the invention.

FIG. 4D is a partial plan view illustrating a fourth example of the connection wiring of the sensor in the detector module for a MEMS sensor illustrated in FIG. 3 according to the first embodiment of the invention.

FIG. 5 is a schematic plan view of a detector module for a MEMS sensor according to a second embodiment of the invention.

FIG. 6 is a schematic cross-sectional view taken along the line B-B of the detector module for a MEMS sensor illustrated in FIG. 5 according to the second embodiment of the invention.

FIG. 7 is a schematic perspective view of an example of the MEMS sensor including the detector module for a MEMS sensor according to an embodiment of the invention.

FIG. 8 is a schematic use state diagram of the MEMS sensor illustrated in FIG. 7 according to an embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

Hereinafter, various embodiments of the present invention will be described in detail with reference to the accompanying drawings.

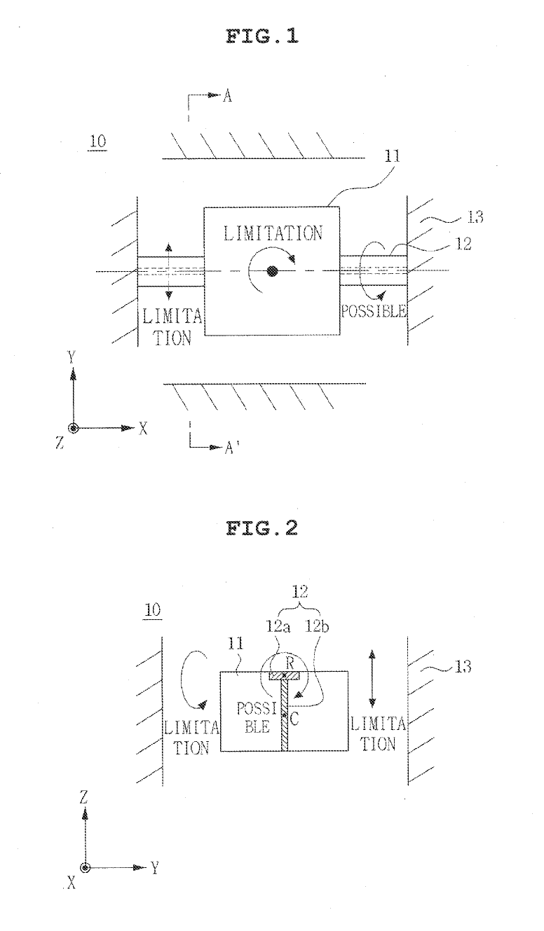

FIG. 1 is a plan view of a detector module for a MEMS sensor according to a first embodiment of the invention, and FIG. 2 is a schematic cross-sectional view taken along the line A-A′ of the detector module for a MEMS sensor illustrated in FIG. 1 according to the first embodiment of the invention.

As illustrated, a detector module 10 for a MEMS sensor includes a mass body 11, a flexible part 12, and a fixed part 13.

According to an embodiment, the flexible part 12 includes a first flexible part 12a and a second flexible part 12b, in which the first flexible part 12a is configured of a beam connecting between the mass body 11 and the fixed part 13 and the second flexible part 12b is configured of a hinge, which extends in an orthogonal direction to a direction in which the first flexible part 12a connects between the mass body 11 and the fixed part 13 and connects between the mass body 11 and the fixed part 13 and limits a displacement direction of the mass body 11.

Hereinafter, a detailed shape of each component, an organic coupling between the respective components, and an acting effect thereof will be described in more detail.

According to an embodiment, the mass body 11 is displaced by inertial force, Coriolis force, external force, as non-limiting examples, and is connected to the fixing part 13 through the first flexible part 12a and the second flexible part 12b.

In this configuration, the mass body 11 is displaced in the state in which the mass body 11 is fixed to the fixing part 13, due to bending of the first flexible part 12a and torsion of the second flexible part 12b when being applied with force. According to an embodiment, the mass body 110 rotates based on the X axis, and the detailed contents thereof will be described below.

Further, an embodiment of the invention illustrates the mass body 11 having a squared pillar shape, but is not limited thereto. Therefore, the mass body 110, according to an embodiment, is formed in all the shapes known to those skilled in the art, such as a cylindrical shape, and a fan shape, as non-limiting examples.

According to an embodiment, the flexible part 120 includes a first flexible part 12a and a second flexible 12b as described above.

Further, the first flexible part 12a and the second flexible part 12b is selectively provided with a sensor, in which the sensor is not particularly limited, but may be formed to use one of a piezoelectric type, a piezoresistive type, a capacitive type, and an optical type, as non-limiting examples.

Further, as described above, the first flexible part 12a is configured of a beam, which connects between the mass body 11 and the fixed part 13. According to an embodiment, the first flexible part 12a is a beam, which has a predetermined thickness in a Z-axis direction and has a surface formed by an X axis and a Y axis. That is, the first flexible part is formed so that a width in the X-axis direction is larger than a thickness in the Z-axis direction.

According to an embodiment, the first flexible part is provided with the sensor. Thus, when viewed based on an XY plane, the first flexible part 12a is relatively wider than the second flexible part 12b, such that the first flexible part 12a is provided with the sensor, which senses a displacement of the mass body 11.

Next, as described above, the second flexible part 12b is configured of a hinge, which extends in an orthogonal direction with respect to a direction in which the first flexible part 12a connects between the mass body 11 and the fixed part 13 and connects between the mass body 11 and the fixed part 13 and limits a displacement direction of the mass body 11. Thus, as illustrated in FIG. 2, with respect to a Y-axis direction, an upper end surface of the second flexible part 12b is coupled with the first flexible part 12a and as illustrated in FIG. 1, and with respect to an X-axis direction, one end surface of the second flexible part 12b is coupled with the mass body 11 and the other end surface thereof is coupled with the fixed part 13. Further, when viewed in a cross section as illustrated in FIG. 2, the second flexible part 12b is vertically coupled with the first flexible part 12a to be formed in a “T”-letter shape.

To be implemented as described above, the second flexible part 12b is configured of a hinge, which has a predetermined thickness in the Y-axis direction and has a surface formed by an X axis and a Z axis. Thus, the second flexible part 12b is formed so that a width in the Z-axis direction is larger than a thickness in the Y-axis direction.

According to an embodiment, the second flexible part 12b is positioned at a central portion with respect to the Y-axis direction of the surface formed by the X axis and the Y axis of the first flexible part 12a.

According to an embodiment, the second flexible part 12b is positioned to correspond to a center of gravity of the mass body 11 based on the X-axis direction.

According to an embodiment, an end surface of the second flexible part 12b is positioned on the same surface with a lower end surface of the mass body 11.

By this configuration, the mass body 11 limitedly rotates based on the Y axis or is limitedly translated in the Z-axis direction, while the mass body 11 may relatively freely rotate based on the X axis.

In detail, as rigidity, when the second flexible part 12b rotates based on the Y axis, is larger than that when the second flexible part 12b rotates based on the X axis, the mass body 11 may freely rotate based on the X axis but limitedly rotates based on the Y axis.

Similarly, as rigidity, when the second flexible part 12b is translated in the Z-axis direction, is larger than that when the second flexible part 12b rotates based on the X axis, the mass body 11 may freely rotate based on the X axis but is limitedly translated in the Z-axis direction. Therefore, as a value of the second flexible part 12 (the rigidity when rotating based on the Y axis or the rigidity when being translated in the Z-axis direction)/(the rigidity when rotating based on the X axis) is increased, the mass body 11 freely rotates based on the X axis, but limitedly rotates based on the Y axis or is limitedly translated in the Z-axis direction.

Further, when the mass body 11 rotates with respect to a rotating center R based on the X axis, the first flexible part 12a is applied with a bending stress which is a combination of a compression stress and a tension stress and the second flexible part 12b is applied with a torsion stress based on the X axis. Further, the second flexible part 12b is provided at a position corresponding to the center of gravity C of the mass body 11 based on the X-axis direction so that the mass body 110 accurately rotates based on the X axis.

According to an embodiment, the first flexible part and the second flexible part of the detector module 10 for a MEMS sensor according to the first embodiment of the invention is integrally formed.

According to an embodiment, the fixed part 13 supports the first flexible part 12a and the second flexible part 12b, so that the mass body 11 is displaced. Further, the fixed part 13 is formed to enclose the mass body 11 and a central portion thereof is fitted with the mass body 11.

By this configuration, the detector module for a MEMS sensor according to the first preferred embodiment of the present invention may remove crosstalk or interference of a resonance mode by the second flexible part and as the second flexible part is connected to the first flexible part to connect the mass body to the fixed part in a one-axis direction, the first flexible part and the second flexible part are implemented as a single flexible part connecting the mass body to the fixed part and thus have reduced rigidity, thereby improving sensitivity.

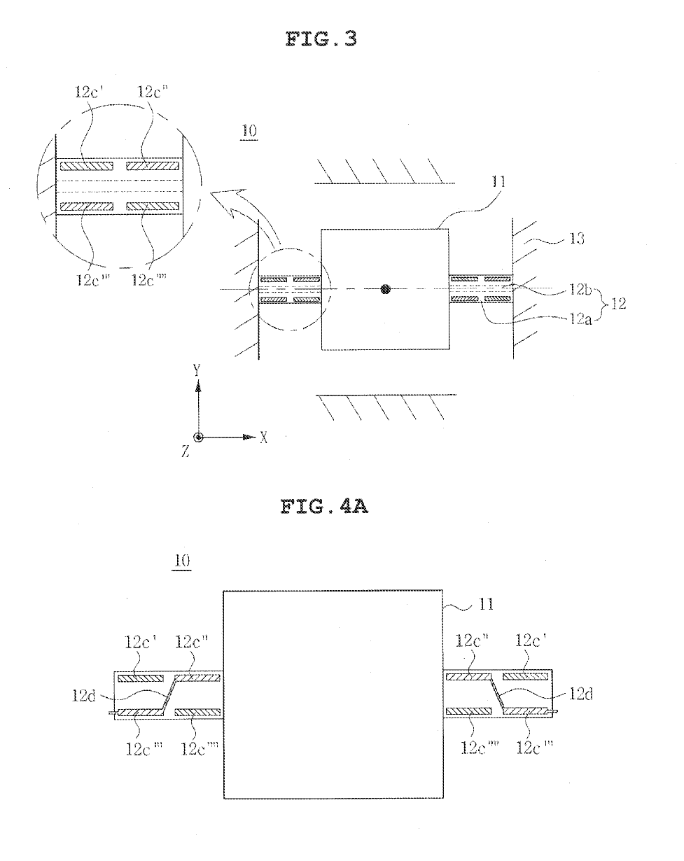

FIG. 3 is a plan view illustrating an example of a sensor, which is formed in the MEMS sensor according to the first embodiment of the invention. As illustrated in FIG. 3, the MEMS sensor 10 is provided with the sensor, in which the sensor is not particularly limited and may be variously formed in the piezoelectric type, the piezoresistive type, the capacitive type, and the optical type, as non-limiting examples, but FIG. 3 illustrates the piezoresistive type sensor as an example of the sensor.

In more detail, the sensor includes a plurality of piezoresistors and wirings connecting between the piezoresistors to measure the bending of the first flexible part 12a and the torsion of the second flexible 12b, thereby sensing the displacement of the mass body 11 rotating based on the X axis.

However, when viewed from an XY plane, the first flexible part 12a is relatively wider than the second flexible part 12b, such that the first flexible part 12a is provided with the sensor which senses the displacement of the mass body 11.

According to an embodiment, the plurality of piezoresistors are configured of a first piezoresistor 12′, a second piezoresistor 12″, a third piezoresistor 12′″, and a fourth piezoresistor 12″″.

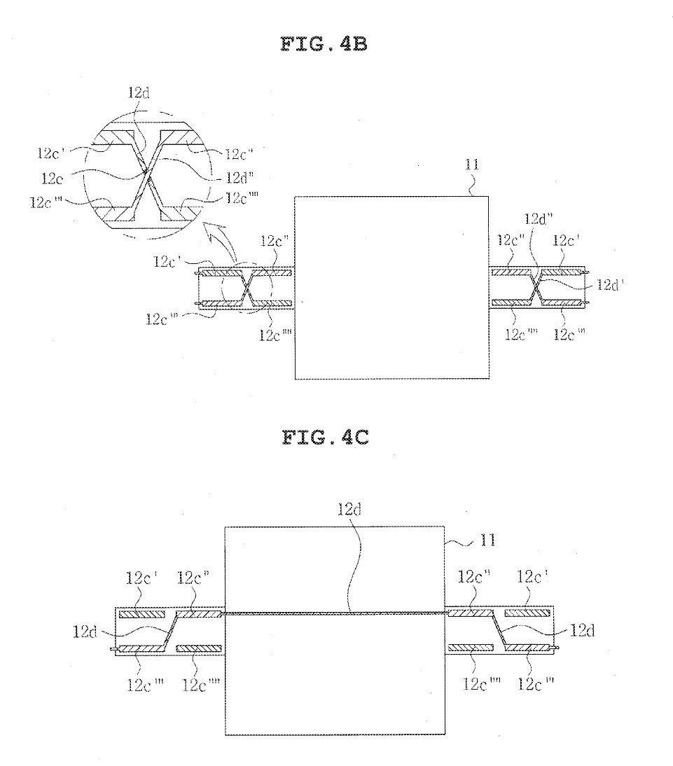

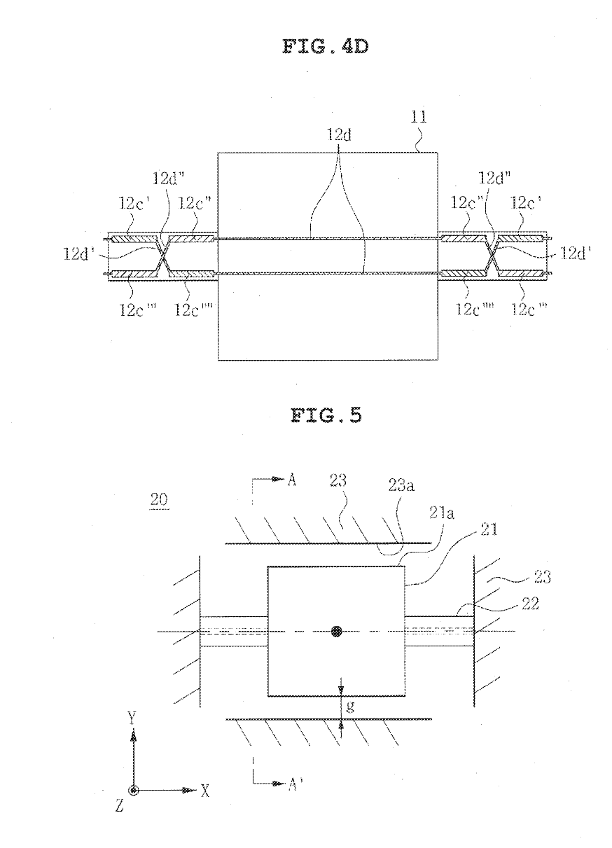

FIG. 4A is a partial plan view illustrating a first example of the wiring of the sensor in the MEMS sensor illustrated in FIG. 3 according to the first embodiment of the invention. As illustrated in FIG. 4A, in the sensor configured of the first piezoresistor 12′, the second piezoresistor 12″, the third piezoresistor 12′″, and the fourth piezoresistor 12″″, the piezoresistors, which are in the same stress state among the plurality of piezoresistors, are connected to each other by the wirings. Thus, when the wirings having different polarities are connected to each other, the wirings are disconnected from each other. Therefore, the disconnection is prevented by separating between the wirings or inserting an insulating layer therebetween.

As an example thereof, FIG. 4A illustrates that the second piezoresistor 12″ and the third piezoresistor 12′″ are connected to each other by a wiring 12d.

FIG. 4B is a partial plan view illustrating a second example of the wiring of the sensor in the MEMS sensor illustrated in FIG. 3 according to the first embodiment of the invention. As illustrated in FIG. 4B, the second piezoresistor 12″ and the third piezoresistor 12′″ are connected to each other by the wiring 12d′ and the first piezoresistor 12′ and the fourth piezoresistor 12″″ are connected to each other by a wiring 12d″. Thus, the wiring 12d′ and the wiring 12d″ connect all of the four piezoresistors of the sensor and have an insulating layer 12a disposed therebetween, and thus the disconnection therebetween is prevented. By this configuration, a signal amplification effect is obtained by using all of the four piezoresistors.

FIG. 4C is a partial plan view illustrating a third example of the wiring of the sensor in the MEMS sensor illustrated in FIG. 3 according to the first embodiment of the invention. As illustrated in FIG. 4C, the wiring according to this third example is different from the wiring according to the first example illustrated in FIG. 4A in that the piezoresistors each disposed at the second flexible parts 12b connected to both sides of the center of the mass body 11 are connected to each other by the wiring.

According to an embodiment, the second piezoresistor 12″ of the second flexible part 12b connected to one portion of the mass body 11 and the second piezoresistor 12″ of the second flexible part 12b connected to the other portion of the mass body 11 are connected to each other by the wiring 12d.

FIG. 4D is a partial plan view illustrating a fourth example of the wiring of the sensor in the MEMS sensor illustrated in FIG. 3 according to the first embodiment of the invention. As illustrated in FIG. 41), the wiring according to the fourth example is different from the wiring according to the second example illustrated in FIG. 4B in that the piezoresistors each disposed at the second flexible parts 12b connected to both sides of the center of the mass body 11 are connected to each other by the wiring.

Thus, the second piezoresistor 12″ of the second flexible part 12b connected to one portion of the mass body 11 and the second piezoresistor 12″ of the second flexible part 12b connected to the other portion of the mass body 11 are connected to each other by the wiring 12d and the fourth piezoresistor 12″″ of the second flexible part 12b connected to one portion of the mass body 11 and the fourth piezoresistor 12″″ of the second flexible part 12b connected to the other portion of the mass body 11 are connected to each other by the wiring 12d.

By this configuration, the number of pads for inputting and outputting a signal of the sensor are reduced.

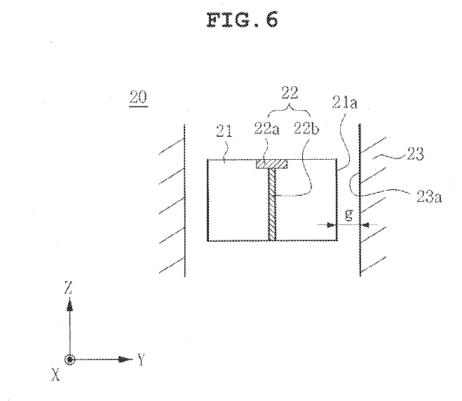

FIG. 5 is a schematic plan view of a detector module for a MEMS sensor according to a second embodiment of the invention, and FIG. 6 is a schematic cross-sectional view taken along the line B-B of the detector module for a MEMS sensor illustrated in FIG. 5 according to the second embodiment of the invention. As illustrated in FIG. 5, a detector module 20 for a MEMS sensor has a difference in only the sensing means, as compared with the detector module 10 for a MEMS sensor according to the first embodiment illustrated in FIG. 3. Thus, the sensor of the detector module 20 for a MEMS sensor is implemented in the capacitive type.

In more detail, the detector module 20 for a MEMS sensor includes a mass body 21, a flexible part 22, and a fixed part 23.

According to an embodiment, the flexible part 22 includes a first flexible part 22a and a second flexible part 22b, in which the first flexible part 22a is configured of a beam connecting between the mass body 21 and the fixed part 23 and the second flexible part 22b is configured of a hinge, which extends in an orthogonal direction to a direction in which the first flexible part 22a connects between the mass body 21 and the fixed part 23 and connects between the mass body 21 and the fixed part 23 and limits a displacement direction of the mass body 21.

According to an embodiment, one surface of the mass body 21 opposite to the fixed part 23 is provided with an electrode part 21a and one surface of the fixed part 23 is provided with an electrode part 23a facing the electrode part 21a of the mass body 21.

By this configuration, when a displacement occurs in the mass body 21, an inertial force is detected by a difference in electrostatic force and capacitance, which occurs in a gap g between the electrode part 21a of the mass body 21 and the electrode part 23a of the fixed part 23.

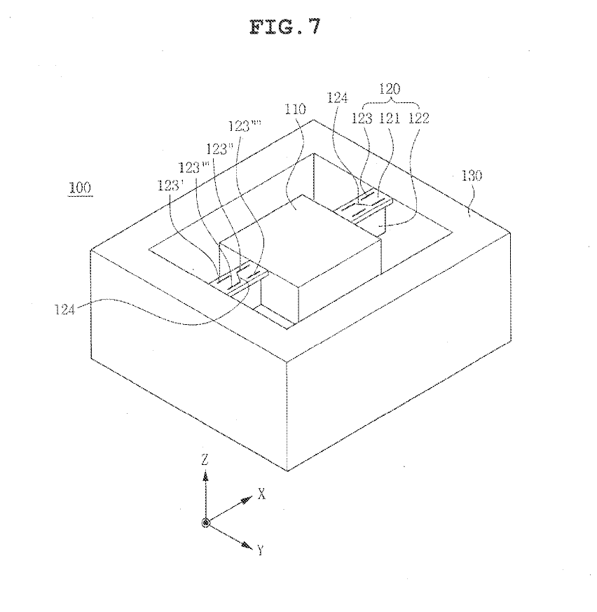

FIG. 7 is a schematic perspective view of an example of the MEMS sensor including the detector module for a MEMS sensor according to another embodiment of the invention.

As illustrated in FIG. 7, a MEMS sensor 100 includes a mass body 110, a flexible beam 120, and a post 130, and may be variously implemented by a pressure sensor or an accelerator sensor, as non-limiting examples, and FIG. 7 illustrates the accelerator sensor as an example of the MEMS sensor 100.

According to an embodiment, the MEMS sensor according to an embodiment of the invention further includes a vibrator and is implemented as the accelerator sensor.

In more detail, the flexible beam 120 includes a first flexible part 121 and a second flexible part 122, in which the first flexible part 121 is configured of a beam connecting between the mass body 110 and the fixed part 130 and the second flexible part 122 is configured of a hinge, which extends in an orthogonal direction to a direction in which the first flexible part 121 connects between the mass body 110 and the fixed part 130 and connects between the mass body 110 and the post 130 and limits a displacement direction of the mass body 110.

According to an embodiment, the, when the mass body 110 is displaced by an external force, the first flexible part 121 coupled with the mass body is applied with a bending stress and the second flexible part 122 coupled therewith is applied with a torsion stress.

As described above, the first flexible part 121 is configured of the beam, which connects between the mass body 110 and the post 130. According to an embodiment, the first flexible part 121 is configured of a beam, which has a predetermined thickness in a Z-axis direction and has a surface formed by an X axis and a Y axis. That is, the first flexible part 121 is formed so that a width in the X-axis direction is larger than a thickness in the Z-axis direction.

According to an embodiment, the first flexible part is provided with the sensor 123, in which the sensor is not particularly limited and may be variously formed in one of a piezoelectric type, a piezoresistive type, a capacitive type, or an optical type, as non-limiting examples, but FIG. 7 illustrates the piezoresistive type sensor as an example of the sensor.

In more detail, the sensor 123 is configured of a first piezoresistor 123′, a second piezoresistor 123″, a third piezoresistor 123′″, and a fourth piezoresistor 123″″ and measures a bending of the first flexible part 121 and a torsion of the second flexible part 122 to be able to sense the displacement of the mass body 110 rotating based on the X axis.

Next, as described above, the second flexible part 122 is configured of a hinge, which extends in an orthogonal direction with respect to a direction in which the first flexible part 121 connects between the mass body 110 and the post 130 and connects between the mass body 110 and the post 130 and limits a displacement direction of the mass body 110. Thus, as illustrated in FIG. 2, with respect to a Y-axis direction, an upper end surface of the second flexible part 122 is coupled with the first flexible part 121 and as illustrated in FIG. 1, and with respect to an X-axis direction, one end surface of the second flexible part 122 is coupled with the mass body 110 and the other end surface thereof is coupled with the supporting part 130. Further, when viewed in a cross section as illustrated in FIG. 2, the second flexible part 122 is vertically coupled with the first flexible part 121 and thus the flexible beam 120 is formed in a “T”-letter shape.

To be implemented as described above, the second flexible part 122 is configured of a hinge which has a predetermined thickness in the Y-axis direction and has a surface formed by an X axis and a Z axis. That is, the second flexible part 122 is formed so that a width in the Z-axis direction is larger than a thickness in the Y-axis direction.

According to an embodiment, the second flexible part 122 is positioned at a central portion with respect to the Y-axis direction of the surface formed by the X axis and the Y axis of the first flexible part 121.

Next, the post 130 supports the first flexible part 121 and the second flexible part 122, so that the mass body 11 is displaced. Further, the post 130 is formed to enclose the mass body 110 and a central portion thereof may be fitted with the mass body 110.

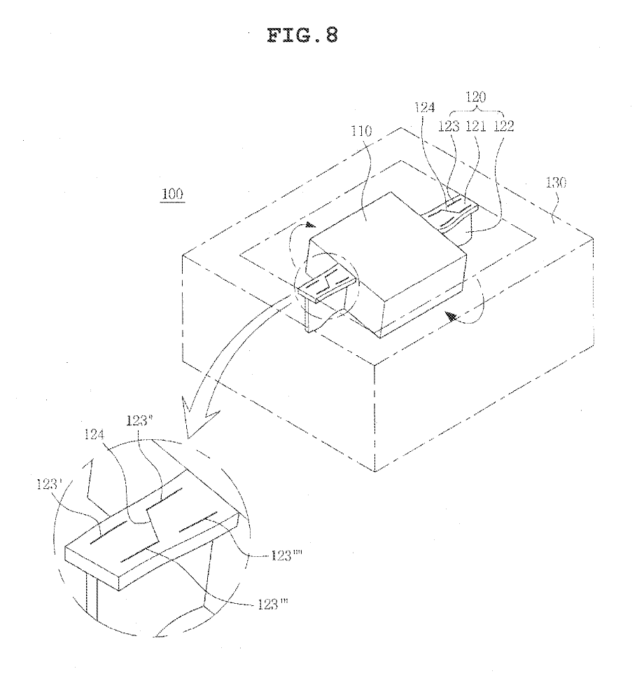

FIG. 8 is a schematic use state diagram of the MEMS sensor illustrated in FIG. 7 according to an embodiment of the invention. As illustrated in FIG. 8, when the mass body 110 is displaced by external force as illustrated, the first flexible part 121 and the second flexible part 122 connected to the mass body 110 are displaced, being interlocked with the mass body 110. In this case, the first flexible part 121 has a bending displacement.

Further, FIG. 8 illustrates an example of the displacement of the mass body 110, in which the mass body 110 has a rotating displacement based on the X-axis direction, which is connected to the second flexible part 122 and therefore the first flexible part 121 has the bending displacement due to expansion and contraction. Further, the first flexible part 121 is provided with a plurality of piezoresistors and a sensor including wirings 124 connecting between the piezoresistors. Further, the plurality of piezoresistors are configured of a first piezoresistor 123′, a second piezoresistor 123″, a third piezoresistor 123′″, and a fourth piezoresistor 123″″ and detect a signal depending on the compression and expansion of the second flexible part. Thus, when the first piezoresistor 123′ and the third piezoresistor 123′″ are compressed, the second piezoresistor 123″ and the fourth piezoresistor 123′″ are tensioned. Further, the accelerator is calculated by the detected signal.

According to an embodiment, in the wirings 124 connected to the plurality of piezoresistors, an example in which the wiring 124 connects between the second piezoresistor 123″ and the third piezoresistor 123″ is illustrated, in which two or four of the first piezoresistor, the second piezoresistor, the third piezoresistor, and the fourth piezoresistor are selectively connected.

According to an embodiment, the plurality of piezoresistors each formed at the second flexible parts, which are connected to both sides of the center of the mass body, are connected to each other by the wirings through the mass body.

By this configuration, the MEMS sensor according to the first embodiment of the invention removes the crosstalk or the interference of the resonance mode by the second flexible part and as the second flexible part is connected to the first flexible part to connect the mass body to the fixed part in the one-axis direction, the first flexible part and the second flexible part are implemented as a single flexible part connecting the mass body to the fixed part and thus have reduced rigidity, thereby improving the sensitivity.

Although various embodiments of the invention have been disclosed for illustrative purposes, it will be appreciated that the present invention is not limited thereto, and those skilled in the art will appreciate that various modifications, additions and substitutions are possible, without departing from the scope and spirit of the invention. Particularly, the present invention has been described based on the X axis, the Y axis, and the Z axis, which are defined for convenience of explanation. Therefore, the scope of the present invention is not limited thereto.

According to the detector module for a MEMS sensor and the MEMS sensor having the same according to the aforementioned embodiments of the invention, it is possible to remove the crosstalk or the interference of the resonance mode and reduce the rigidity using the single flexible part to improve the sensitivity.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A detector module for a MEMS sensor, the detector module comprising:
a mass body;
a fixed part disposed to be spaced apart from the mass body; and
a flexible part configured to connect the mass body to the fixed part,
wherein the flexible part comprises a first flexible part, which is a beam configured to connect the mass body to the fixed part, and a second flexible part, which is a hinge configured to extend to the first flexible part, to connect the mass body to the fixed part, and to limit a displacement of the mass body.

2. The detector module as set forth in claim 1, wherein the second flexible part is configured to extend in an orthogonal direction to a direction in which the first flexible part connects the mass body to the fixed part.

3. The detector module as set forth in claim 1, wherein the first flexible part is a beam having a predetermined thickness in a Z-axis direction and having a surface formed by an X axis and a Y axis and is formed so that a width in an X-axis direction is larger than a thickness in a Z-axis direction.

4. The detector module as set forth in claim 1, wherein the second flexible part is a hinge having a predetermined thickness in a Y-axis direction and having a surface formed by an X axis and a Y axis and is formed so that a width in a Z-axis direction is larger than a thickness in a Y-axis direction.

5. The detector module as set forth in claim 4, wherein the second flexible part is positioned corresponding to a center of gravity of the mass body based on the X-axis direction.

6. The detector module as set forth in claim 1, wherein one end surface of the second flexible part is vertically coupled with the first flexible part and the end surface thereof is formed in a “T”-letter shape.

7. The detector module as set forth in claim 6, wherein the other end surface of the second flexible part is positioned on the same surface with a lower end surface of the mass body.

8. The detector module as set forth in claim 1, wherein the first flexible part is applied with a bending stress and the second flexible part is applied with a torsion stress, by the displacement of the mass body.

9. The detector module as set forth in claim 1, wherein one surface of the first flexible part or the second flexible part is selectively provided with a sensor configured to sense the displacement of the mass body.

10. The detector module as set forth in claim 9, wherein the sensor comprises a plurality of piezoresistors and wirings connecting between the piezoresistors.

11. The detector module as set forth in claim 10, wherein the plurality of piezoresistors comprise a first piezoresistor, a second piezoresistor, a third piezoresistor, and a fourth piezoresistor, and the piezoresistors, which are in the same stress state among the plurality of piezoresistors, are connected to each other by the wirings.

12. The detector module as set forth in claim 11, wherein two or four of the first piezoresistor, the second piezoresistor, the third piezoresistor, and the fourth piezoresistor are selectively connected to each other by the wirings.

13. The detector module as set forth in claim 9, wherein the second flexible parts are each connected to both sides of the mass body, the second flexible parts are each provided with the plurality of piezoresistors, and the plurality of piezoresistors are connected to each other by the wirings through the mass body.

14. The detector module as set forth in claim 1, further comprising:
a sensor configured to detect the displacement of the mass body, wherein the sensor comprises an electrode part formed on one surface of the mass body and an electrode part formed at the fixed part facing the electrode part of the mass body.

15. A MEMS sensor, comprising:
a mass body;
a post fitted with the mass body; and
a flexible beam configured to connect the mass body to the post,
wherein the flexible beam comprises a first flexible part, which is a beam configured to connect the mass body to the post, a second flexible part, which is a hinge coupled with the first flexible part, configured to connect the mass body to the post, and to limit a displacement of the mass body, and a sensor selectively provided on one surface of the first flexible part or the second flexible part and configured to sense the displacement of the mass body.

16. The MEMS sensor as set forth in claim 15, wherein the second flexible part is configured to extend in an orthogonal direction to a direction in which the first flexible part connects the mass body to the post.

17. The MEMS sensor as set forth in claim 15, wherein the first flexible part is a beam, which has a predetermined thickness in a z-axis direction and has a surface formed by an X axis and a Y axis and the second flexible part is a hinge, which has a predetermined thickness in a Y-axis direction and has a surface formed by the X axis and a Z axis.

18. The MEMS sensor as set forth in claim 15, wherein one end surface of the second flexible part is vertically coupled with the first flexible part to form an end surface of a flexible beam in a “T”-letter shape.

19. The MEMS sensor as set forth in claim 15, wherein the sensor comprises a plurality of piezoresistors and wirings connecting between the piezoresistors.

20. The MEMS sensor as set forth in claim 19, wherein the plurality of piezoresistors comprise a first piezoresistor, a second piezoresistor, a third piezoresistor, and a fourth piezoresistor, and the piezoresistors, which are in the same stress state among the plurality of piezoresistors, are connected to each other by the wirings.

21. The MEMS sensor as set forth in claim 20, wherein two or four of the first piezoresistor, the second piezoresistor, the third piezoresistor, and the fourth piezoresistor are selectively connected to each other by the wirings.
